(19) United States
(12) Patent Application Publication
(10) Pub. No.: US 2002/0115315 A1
(43) Pub. Date: Aug. 22, 2002

(54) Burn in socket

(76) Inventor: Gary A. Clayton, Meridian, ID (US)

Correspondence Address: ROBERT L. SHAVER, DYKAS & SHAVER, LLP, P.O. BOX 877, BOISE, ID, 83701-0877, US

(21) Appl. No.: 10/043,459

(22) Filed: Jan. 1, 2002

Related U.S. Application Data
(60) Provisional application No. 60/261,253, filed on Jan. 10, 2001.

(51) Int. Cl. H05K 1/00

(52) U.S. Cl. 439/70

(57) ABSTRACT

A removable chip socket for mounting on printed circuit boards and for holding an electrical chip into an electrical engagement with the circuitry of the printed circuit board. When used in a bum-in board, individual chip sockets can be replaced as necessary. The removable chip socket also includes replaceable connection posts, which can be changed to repair bad electrical connections.

### PRIORITY

This application is related to provisional patent application No. 60/261,253, filed on Jan. 10, 2001, by the same inventor and commonly assigned, the contents of which are incorporated herein by reference.

### DESCRIPTION

### BACKGROUND OF THE INVENTION

Field of the Invention. The present invention generally relates to sockets for securing chips to printed circuit boards, and more particularly relates to sockets which are removable and replaceable on a bum-in-board and which secure a computer or IC (integrated circuit)chip in place.

Background Information. In the prior art, a chip is placed on one of numerous sockets of a burn-in-board for testing during the manufacturing process. The burn-in socket in turn is permanently attached to a load board by solder connections. The electrodes of the IC chip connect to leads on the burn-in socket, which are soldered to the corresponding leads on the load board. Over time, tin lead solder on the electrodes of the IC chip tend to contaminate the leads of the burn-in socket. When one of the leads of any burn-in socket becomes sufficiently contaminated with tin lead solder from a chip, that burn-in socket ceases to be useful for testing IC chips. The burn-in socket can be cleaned, but the cleaning solution is such that after about two such cleanings, the burn-in socket becomes inoperable because some of the metal has been etched away in the cleaning process. When enough burn-in sockets are deactivated in this way, that section of the load board itself is inoperative.

This disclosure is for an improved device for securing a chip to a circuit board, with special usefulness in burning in and/or testing computer chips. This disclosure is also for an improved device for testing computer chips with test handlers or lab type testing.

Before a computer chip is sold, it is placed on a burn-in-board in a socket site. The burn-in-board has electrical connections to each of the electrical connections of the chip, via the socket, and is used to test the chip by cycling on and off repeatedly. The cycling on and off subjects the chip to thermal and electrical stress, and when the chip is on, the functions of the chip may be tested through the burn-in-board. A burn-in-board is a printed circuit board with a large number of locations for chips to be inserted. The electrodes of the chip interact with electrodes on the burn-in-board, typically through the socket. The burn-in-board is typically an array with a large number of chip locations on it.

One problem with the prior art burn-in-boards is that each chip location has connections that are permanently soldered in place. After repeated use, a socket can go bad for various reasons. When that happens, the burn-in-board continues in use, but that particular socket is noted and is no longer used. After a period of use, a number of sockets on the burn-in-board may be inoperable, and at some point, the entire burn-in-board is scrapped, because too many sockets are no longer functional.

The older generation of computer chips interfaces with a printed circuit board by a number of finger-like electrodes. This type of electrode is preferably used for low frequency applications, but in higher frequency applications, newer chips utilize electrodes that are more like a bump of conductive material than like a finger-like extension.

Another problem, which arises with printed circuit boards, is when a particular chip may need to be replaced. Presently, a particular chip is usually soldered in place, or pressed into place securely. However, newer chips do not have long electrodes that can be placed into an electrode receiver, and a new way of replacing a particular chip is required. A chip may need to be replaced because the electrodes connecting the chip have become corroded, or a newer version of the chip may be desired. This is particularly true on the motherboard of computers in which it would be desirable to replace the CPU chip in order to upgrade to a newer model of CPU. This would allow replacement of a single chip, rather than replacing the entire computer or motherboard in order to upgrade.

Accordingly, it is an object of the invention to provide a device that allows the replacement of individual chips on a printed circuit board. It is a further object of the invention to provide a chip socket, which is replaceable, so that individual sockets on a burn-in board or other printed circuit board may be replaced. It is also an object of the invention to provide a device in which the electrical connection between a chip and the printed circuit board can be replaced by the use of replaceable connections. These and other objects are accomplished by the device of the invention.

### SUMMARY OF THE INVENTION

The invention is a removable chip socket for mounting on a circuit board. It is for use on any circuit board on which electrical chips are mounted, but is of particular utility on burn in boards. The device will be termed a removable chip socket, a term which should be considered to be interchangeable with “burn in socket.” The unit it attaches to will be called a circuit board, a term which should be considered to be interchangeable with “burn in board.” The device operates with electrical chips, which have electrical conductors such as fingerlike electrodes, bumps, or pads. The circuit board has electrical leads, which are made to have electrical contact with the electrical conductors of the chip, and which form a circuit on the circuit board. The removable chip socket connects to the printed circuit, and establishes an electrical connection between the printed circuit and the chip held in the removable chip socket. The removable chip socket can connect to the printed circuit by the use of conventional electrodes, spring probes, or a conductive-layered sheet called an interposer. One type of interposer is disclosed in a previously filed patent application, filed Oct. 4, 2000, with Gary Clayton as the inventor. The removable chip socket has a means of aligning itself accurately on the printed circuit. This would typically be one or more alignment posts, and can also be screws, bolts or pins, which accurately position the removable chip socket to the printed circuit. When used with an interposer, the interposer is placed on the bottom surface of the removable chip socket, and the removable chip socket with the interposer attached is placed on the printed circuit. The interposer is aligned and attached to the removable chip socket by screws, posts, adhesive, friction, or any other means required.

The removable chip socket includes a socket base, which is configured for releasable mounting on the circuit board. The socket base includes an internal well in which a chip is positioned. The internal well of the socket base positions and secures the electrical chip so that its electrical conductors are in accurate alignment with conductive components of the socket base, called connection posts. The electrical chip is secured within the internal well of the socket base with a chip-securing collar, which can be of a number of configurations. The electrical conductors of the chip come into contact with a number of connection posts within the socket base. These connection posts serve the purpose of establishing electrical connections between the electrical conductors of the chip and the electrical leads of the circuit board. The socket base includes attachment pins that allow the socket base to be releasably attached to the circuit board.

The connection posts of the device can take a number of forms. In one form, the connection posts are spring probes, which have a tip projecting from each end of the cylindrically shaped spring probe. Both tips are spring loaded and variously pointed, so that corrosion on electrical leads can be penetrated and electrical connection made. The points can be conically pointed, or toothed or lobed on the outside circumference of the probe.

Another type of connection post can be formed using an interposer. One type of interposer is an elastomeric sheet in which particles, which are conductive and metallic, are interspersed throughout an insulating matrix. When pressure is applied on both sides of this type of interposer in a particular location, the elastomeric material is compressed, and sufficient metallic particles come into contact to form an electrical pathway. This type of interposer forms a number of connection posts which are temporary in nature, and are formed as a result of compression of both sides of the interposer.

Another type of connection post is formed from an interposer which is a sheet of insulative material in which are formed a number of conductive pads which conduct electricity from one side of the sheet to another side of a sheet. The conductive pads of this type of interposer can by simple copper pads. The copper pads can also be layered so that each copper pad is topped by a layer of elastomeric material which includes metallic and conductive particles. The device can also work with a type of interposer which is formed by conductive pads which are positioned on an insulating sheet, in which each conductive pad is formed of conductive and metallic particles bound within a flexible matrix.

The device can be configured with a number of different types of attachment pins. One type of attachment pin utilizes screws which extend through the socket base and attach the socket base to the circuit board. The screws can thread into the circuit board itself. They can also pass through the circuit board and thread into a backing board or nuts which correspond to each screw. The number of screws utilized is not critical, but the attachment must be sufficiently secure and accurate so that the electrical connections between the socket base and the circuit board are in alignment. The attachment pins may also be screws which are attached to the circuit board and which inter-fit with corresponding holes in the socket base in order to hold the socket base in alignment on the circuit board.

One configuration of the device includes a socket top assembly. This assembly has a central chip passage through which a chip may be passed into the internal well of the socket base. The socket top assembly of this embodiment is interconnected with a zero insertion force collar which is made of several parts. These parts include a first and second shoulder of the zero insertion force collar. The shoulders press the chip into connection with the connection posts of the socket base. If the removable chip socket were to be used in a burn-in board, the burn-in board would typically have an array of removable chip sockets on its surface. If any one of the chips develops electrical connection, that removable chip socket could be replaced. The connecting posts within each chip socket could also be replaced. In the case of spring probes, individual spring probes could be replaced. In the case of connecting posts which utilize interposers, the individual interposer could be replaced.

If used in a burn-in-board setting, a number of these removable chip sockets are placed on the burn-in-board, and chips are placed in each of the removable chip sockets. With this device, when one socket malfunctions, an individual removable chip socket may be replaced, rather than eventually scrapping the entire burn-in-board due to malfunctioning sockets. The removable chip socket can also be repaired, and allows the use of either an interposer or a conventional socket connection. Besides use in burn-in-boards, the removable chip socket can be used individually on a board, and thus allows the easy replacement of a particular chip.

The body of the removable chip socket is made of Torlon or other electrically suitable material, and is typically 1.5″×1.5″ in size. It is approximately 0.75″ high.

Still other objects and advantages of the present invention will become readily apparent to those skilled in this art from the following detailed description wherein I have shown and described only the preferred embodiment of the invention, simply by way of illustration of the best mode contemplated by carrying out my invention. As will be realized, the invention is capable of modification in various obvious respects all without departing from the invention. Accordingly, the drawings and description of the preferred embodiment are to be regarded as illustrative in nature, and not as restrictive.

### BRIEF DESCRIPTION OF THE DRAWINGS

FIG. 1 is a perspective view of a prior art chip connection to a socket on a printed circuit.

FIG. 2 is a perspective exploded view of a first embodiment of the removable chip socket.

FIG. 3 is a perspective view of the underside of the socket base of the first embodiment.

FIG. 4 is a side cross-sectional view of a spring probe of the first embodiment.

FIG. 5 is a cross-sectional view of the socket base of the first embodiment.

FIG. 6 is a perspective view of a second embodiment of the device.

FIG. 7 is a side cross-sectional view of the second embodiment of the device.

FIG. 8 is a perspective cross sectional view of the second preferred embodiment of the device.

FIG. 9 is a cross sectional view of the second preferred embodiment of the device.

FIG. 10 is a perspective cross sectional view of the second embodiment of the invention.

FIG. 11 is an exploded view of the second embodiment of the invention.

### DESCRIPTION OF THE PREFERRED EMBODIMENTS

While the invention is susceptible of various modifications and alternative constructions, certain illustrated embodiments thereof have been shown in the drawings and will be described below in detail. It should be understood, however, that there is no intention to limit the invention to the specific form disclosed, but, on the contrary, the invention is to cover all modifications, alternative constructions, and equivalents falling within the spirit and scope of the invention as defined in the claims.

While there is shown and described the present preferred embodiment of the invention, it is to be distinctly understood that this invention is not limited thereto but may be variously embodied to practice within the scope of the following claims.

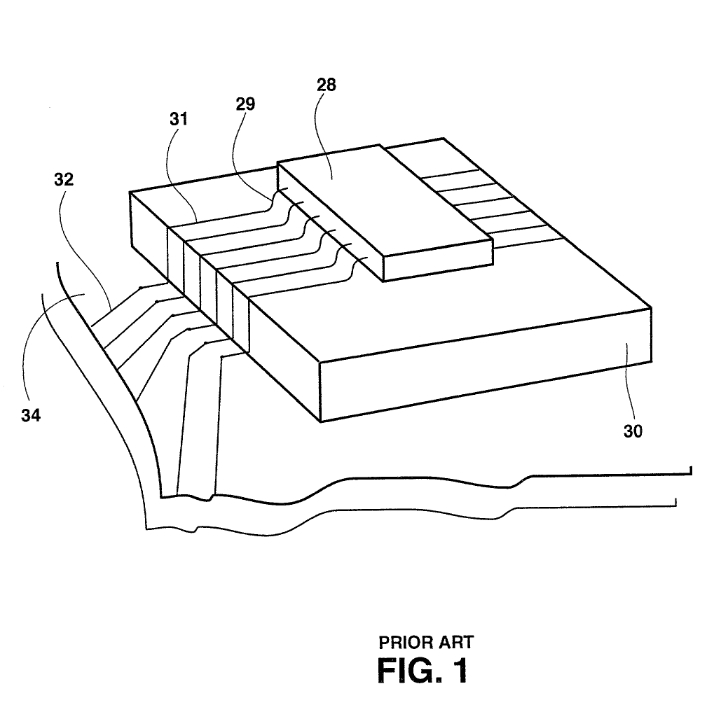

FIG. 1 shows a prior art socket, in a typical configuration as a chip is inserted and tested on a test board. Chip 28 is shown in contact with prior art burn-in socket 30, on printed circuit 34. Prior art burn-in socket 30 has electrical leads 32 which extend to the circuit board 34 and are soldered in place to connect with electrical leads on circuit board 32. The chip 28 includes electrical conductors 29, which connect with the electrical leads on the burn-in socket. The problem with this configuration is that the connection between 29 and 31 inevitably become corroded, and the burn-in socket 30 becomes inoperable. Since it is soldered in place, this particular chip holding socket cannot be used. This situation occurs in burn-in boards as well as in any printed circuits which contain chips. It is particularly troublesome in burn-in sockets because a large number of chips are inserted and removed from the burn-in socket.

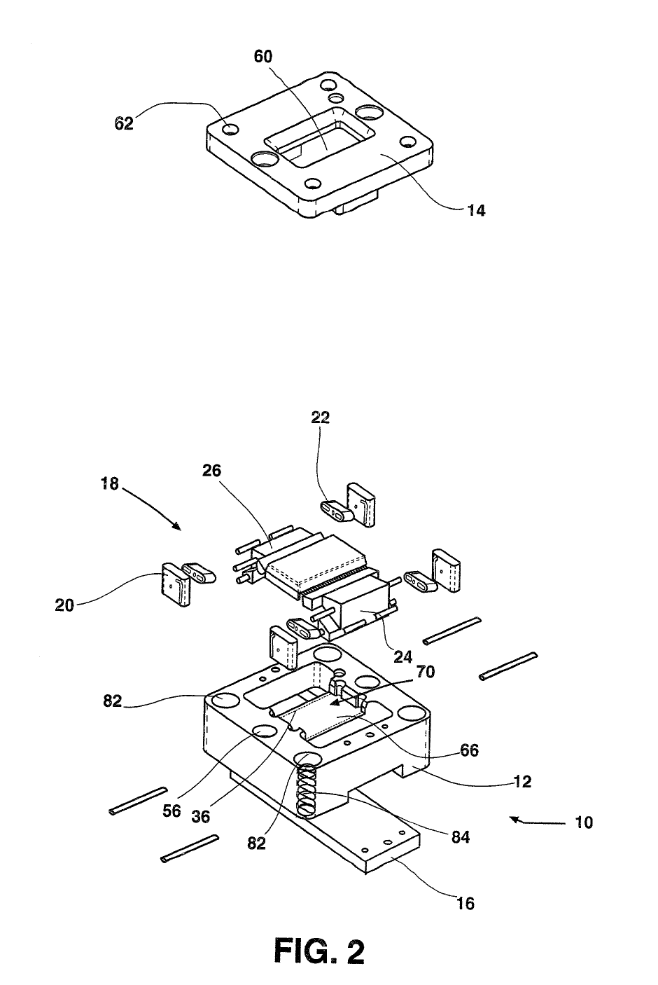

FIGS. 2 through 7 illustrate the removable chip socket of the invention. FIG. 2 shows a first preferred configuration of the invention. This configuration includes a socket base 12 in which are mounted various components of a zero insertion force (ZIF) assembly 18. These include a ZIF guidepost 20, ZIF link blocks 22, a ZIF first shoulder 24, and a ZIF second shoulder 26. The components of the ZIF assembly 18 interact with a socket top assembly 14. The socket top assembly 14 includes a chip passage 60, and alignment holes 62 through which an alignment screw passes. The socket base 12 also has a number of alignment holes 56, through which an alignment screw passes, and which attaches the removable chip socket 10 to the underlying circuit board (not shown).

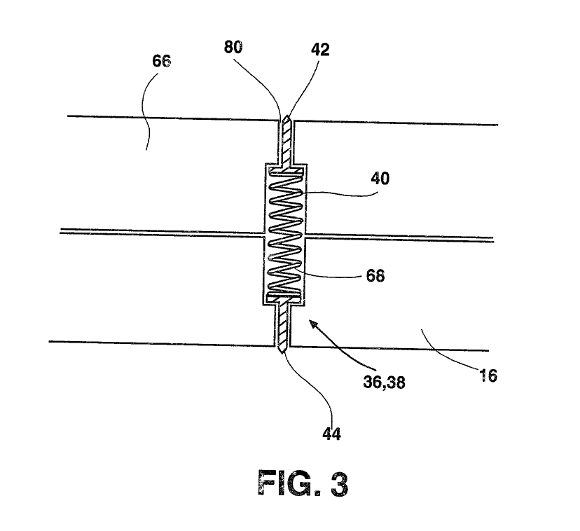

The socket base 12 also includes a top pin plate 66. In this version, the top pin plate 66 is built into the socket base 12. It could also be a bolt in or snap in component. The top pin plate 66 includes a number of spring probe openings 80. These are shown more fully in FIG. 3. FIG. 3 shows a single spring probe 38 mounted in cavities between the top pin plate 66 and the bottom pin plate 16. The spring probe 38 includes a spring probe body 40, an internal spring 68, a top spring probe 42, and a bottom spring probe 44. When mounted in the socket base as shown, these spring probes serve as the connection posts 36 of the device. In this role, they provide an electrical connection between a chip being tested in the inner well of the socket base 12, and the circuit to which the chip needs to be electrically connected, on the printed circuit below.

In operation, in this particular configuration of the device, the socket top assembly 14 is pressed down against the socket base 12. This releases and withdraws the ZIF first shoulder 24 and the ZIF second shoulder 26. At that time, a chip (not shown) is either manually or by automated means, dropped into place through the chip passage 60 of the socket top assembly 14 into the inner well 70 of the socket base 12. When the socket top assembly 14 is released, it moves upward as a result of springs, and the ZIF first shoulder 24 and the ZIF second shoulder 26 move into place to secure the chip against the top spring probe 42 of the array of connection posts 36. At that time, the chip is locked in place and electrically connected to the circuit board below, and thermal cycling and tests of the functions of the chip can proceed. When the testing is done, the chip is removed by pressing down on the socket top assembly 14 and lifting the chip out of the inner well 70 of the socket base 12.

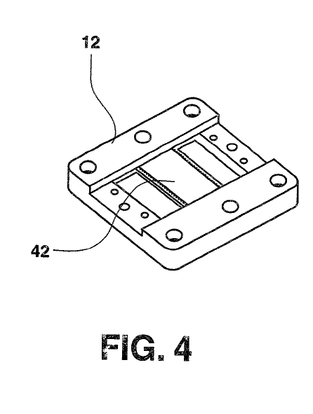

FIG. 4 shows the underside of socket base 12, with the bottom spring probes 44 visible.

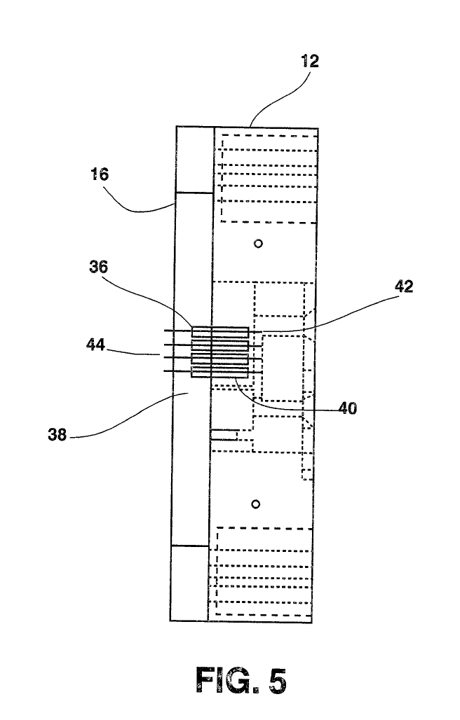

FIG. 5 is a cross-section of the socket base 12 of this embodiment, showing the spring probe bodies 40 of several spring probes 38 and the top spring probe 42 and the bottom spring probe 44 projecting for electrical connection with a chip and a circuit board, respectively.

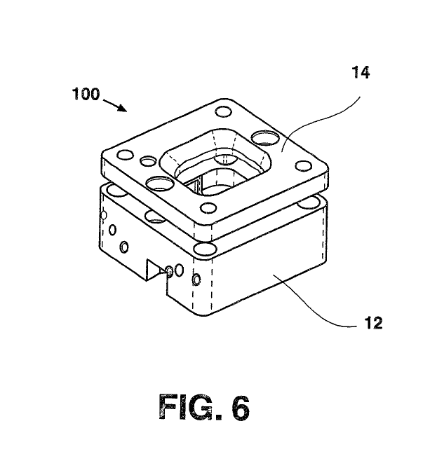

FIG. 6 shows a second preferred embodiment 100 of the invention. This device also has a socket base 12 and a socket top assembly 14 and the same ZIF assembly 18 as shown in the first embodiment. This embodiment is lacking a bottom pin plate 16 because it does not use spring probes for the connection posts. Instead, it utilizes an interposer 72.

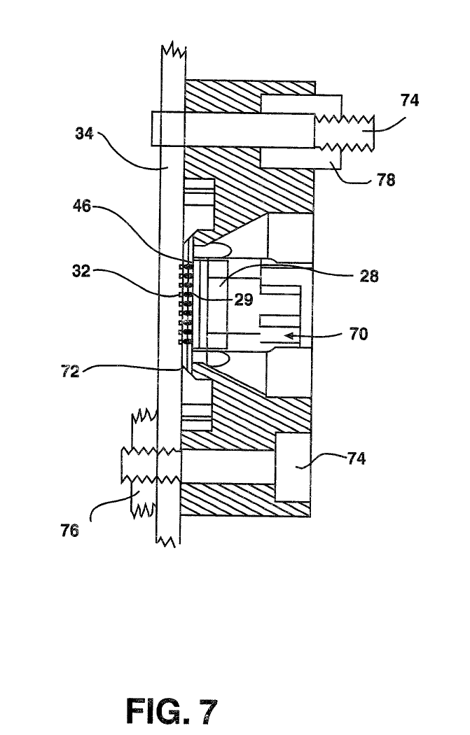

FIG. 7 is a cross-sectional view of the second preferred embodiment 100 shown with a chip 28 in place, and electrical contact with said chip 28 made by means of an interposer 72. Attachment bolts 74 are shown attaching the removable chip socket 100 to a circuit board 34, by means of a backing plate 76 or a nut 78. As shown, the screws can pass through the socket base 12 and be bolted to the circuit board, or they can extend from the circuit board side with the nut on the top of the socket base 12. As shown, the interposer 72 forms the electrical connection between the electrical leads on the circuit board 32 and the electrical conductors 29 of the chip 28.

The interposer used can include any type of interposer. One type that is commonly used is an interposer formed of an elastomeric material in which are embedded a number of metallic granules. These granules are conductive, and when the elastomeric material is compressed from above and below, the metallic granules come into contact with each other and form one or more pathways for electricity from the top surface to the bottom surface of the interposer. Another type of interposer which is used with the preferred embodiment of removable chip socket 100 is a type of interposer which is formed on a membrane of insulating material. Located on the membrane are a number of conductive pads, which correspond to conductor and lead locations on the chip 28 and the printed circuit 32. These conductive pads can be made of copper or other conductive material. They can also be made of copper with a layer of elastomeric material plus metallic granules on each exterior surface of the conductive pads. Another form of conductor for this type of interposer includes conductive pads which are made entirely of elastomeric material with embedded metallic granules. These can be in the form of dumbbells, when cut in cross sections, with a connecting column with a disc-shaped conductive pad which extends on either side of the insulating sheet of the interposer. The second preferred embodiment 100 can work with these or any other type of interposer.

In this embodiment, when an electrical connection of the device becomes defective, the interposer can be changed. If necessary, the removable chip socket 100 can also be removed and replaced.

As with the first preferred embodiment, use of this removable chip socket 100 would have particular application in a burn-in board, but it would also be useful in any situation where a particular chip, or chip socket, might need to be replaced.

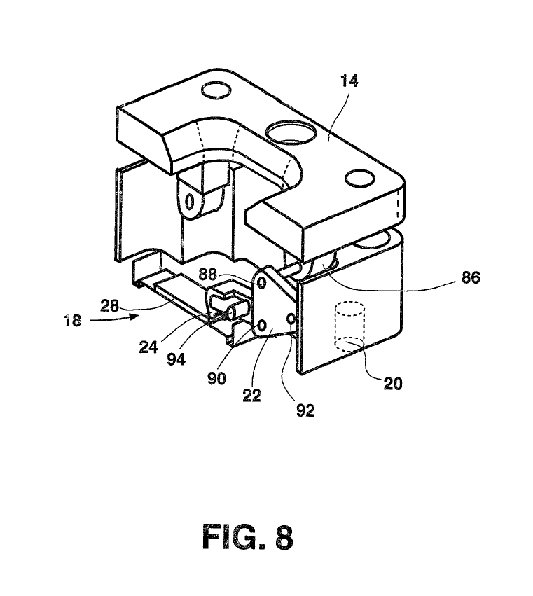

In a preferred embodiment, the removable chip socket utilizes a socket top assembly and a zero insertion force assembly. The first and second preferred embodiment both preferably utilize a similar socket top assembly 14 and ZIF assembly 18. FIG. 8 is a perspective cross-sectional view of the socket top assembly 14 and ZIF assembly 18 of the second embodiment of the invention. The socket top assembly 14 includes a linkage post 86 which is connected by a linkage pin 88 to a ZIF link block 22. The ZIF link block 22 is attached by link pin 90 to a ZIF first shoulder 24. ZIF link block 22 is also linked by a link pin 92 to a ZIF guidepost 20. Within ZIF guidepost 20 is defined a curved slot through which link pin 94, which passes through ZIF first shoulder 24, travels. Thus, when the socket top assembly 14 is pressed down, linkage post 86 with its enclosed link pin 88 causes ZIF link block 22 to rotate around link pin 92. In the rotation of ZIF link block 22, ZIF first shoulder 24 is caused to lift off its contact with chip 28, and to move laterally away from chip 28. Thus, in a depressed position of socket top assembly 14, the chip 28 is released and may be removed from the inner well 70 of the socket base 12. Only one side of the ZIF assembly has been described, but it is to be understood that the opposite side contains the same components in mirror image and operates in the same manner.

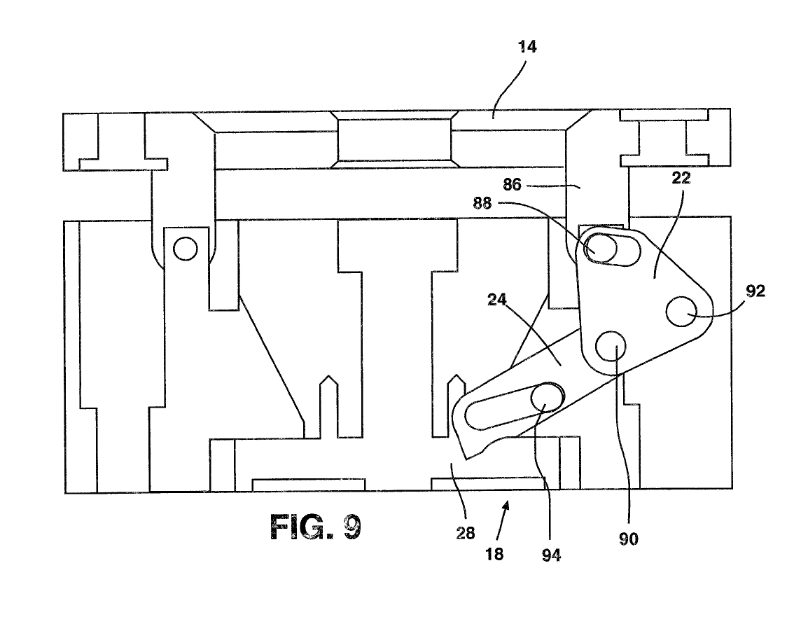

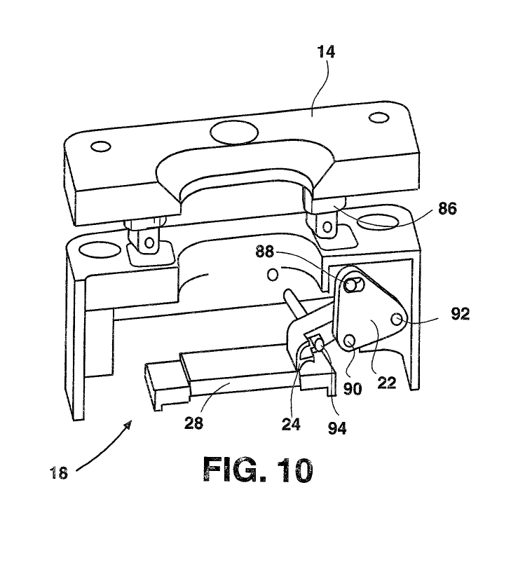

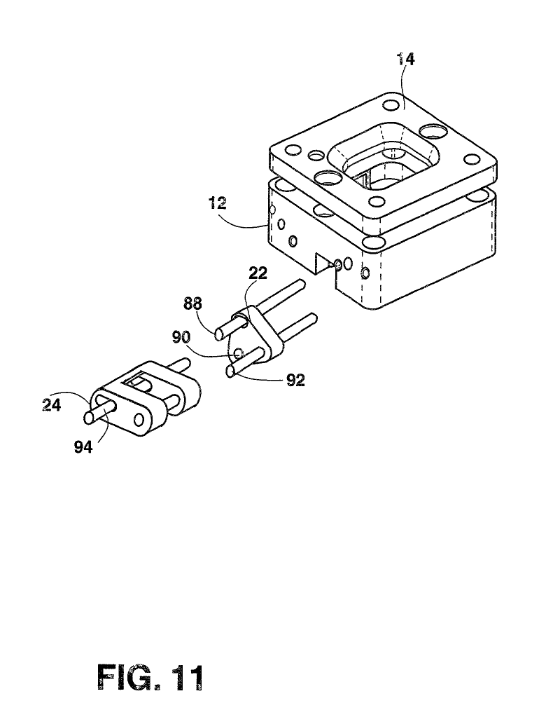

FIGS. 9 and 10 show a cross-section view of the second preferred embodiment of the device with the components of the ZIF assembly shown in side view. FIG. 11 is an exploded view of the ZIF assembly.

The ZIF assembly for the first preferred embodiment of the invention has very similar components, but they are shaped slightly differently because different amount of lateral travel is required when using spring probes as opposed to an interposer as connection posts. Although shaped slightly different to achieve a slightly different amount of travel, the components are equivalent and perform the same function.

From the foregoing description, it will be apparent that various changes may be made without departing from the spirit and scope of the invention as defined by the following claims.

I claim:

1. A removable chip socket for mounting on a circuit board, said circuit board containing electrical leads, and said removable chip socket for holding an electrical chip with electrical conductors in electrical contact with said circuit board, said removable chip socket comprising:
a socket base configured for releasable mounting on said circuit board, for positioning and securing said electrical chip with electrical conductors; a chip securing collar attached to said socket base for securing said electrical chip in accurate alignment in said socket base;
a plurality of connection posts in said socket base for establishing an electrical connection between said electrical conductors of said electrical chip and said electrical leads of said circuit board; and
one or more attachment pins for releasably attaching said socket base to said circuit board.

2. The removable chip socket of claim 1 in which said connection posts are configured for individual replacement.

3. The removable chip socket of claim 2 in which said connection posts are spring probes with a spring probe body, with a top spring probe tip extending from a first end of said spring probe body, and a bottom spring probe tip extending from a bottom end of spring probe body, with said spring probes mounted in said socket base between said socket base and a pin plate, so that said top spring probe tip extends through said socket base for contact with said electrical conductors of said chip, and said bottom spring probe tip extends through said pin plate for contact with said electrical leads of said printed circuit.

4. The removable chip socket of claim 1 in which said connection posts are located on an interposer, and said interposer is configured for replacability.

5. The removable chip socket of claim 4 in which said connection posts are conductive contact pads mounted on an interposer formed of insulating material.

6. The removable chip socket of claim 1 in which said attachment pins are screws which extend through said socket base and attach said socket base to said circuit board.

7. The removable chip socket of claim 6 in which said attachment pins are screws which extend through said socket base and through said circuit board, and are held in place by a backing board.

8. The removable chip socket of claim 6 in which said attachment pins are screws which extend through said socket base and through said circuit board, and are held in place by corresponding nuts.

9. The removable chip socket of claim 1 in which said attachment pins are screws attached to said circuit board, which interfit with corresponding holes in said socket base, to hold said socket base in place on said circuit board.

10. The removable chip socket of claim 1 in which said attachment pins are posts attached to said circuit board, which interfit with corresponding holes in said socket base, to hold said socket base in place on said circuit board

11. The removable chip socket of claim 1 in which said chip securing collar is a zero insertion force collar, which holds said chip in place in said socket base.

12. The removable chip socket of claim 11 which further includes a socket top assembly, which defines a chip passage through which a chip may be passed to said socket base, and which is linked to a zero insertion force collar assembly for holding said chip in place in said socket base.

13. The removable chip socket of claim 12 in which said zero insertion force collar assembly includes a first shoulder and a second shoulder, which press said chip into connection with said connection posts.

14. A removable chip socket for mounting on a circuit board, said circuit board containing electrical leads, and said removable chip socket for holding an electrical chip with electrical conductors in electrical contact with said circuit board, said removable chip socket comprising:
a socket base configured for releasable mounting on said circuit board, for positioning and securing said electrical chip with electrical conductors;
a chip-securing collar attached to said socket base for securing said electrical chip in accurate alignment in said socket base;
a plurality of spring probes, each with a spring probe body, a top spring probe tip extending from a first end of said spring probe body, and a bottom spring probe tip extending from a bottom end of spring probe body, with said spring probes mounted in said socket base between said socket base and a pin plate, so that said top spring probe tip extends through said socket base for contact with said electrical conductors of said chip, and said bottom spring probe tip extends through said pin plate for contact with said electrical leads of said printed circuit; and
one or more attachment pins for releasably attaching said socket base to said circuit board.

15. The removable chip socket of claim 14, in which said chip securing collar comprises a socket top assembly, one or more springs enclosed in a spring well in said socket base and said socket top assembly, and one or more ZIF guide posts, one or more ZIF link blocks, one or more ZIF shoulders, and a plurality of connecting pins which interfit with said ZIF guide posts, ZIF link blocks, and ZIF shoulders, whereby pressing on said socket top assembly biases said springs in said spring wells, and moves said socket top assembly toward said socket base, and also moves said ZIF shoulders in a path guided by said ZIF guide posts and said ZIF link blocks, to a position away from engagement with a chip in said removable chip socket, and whereby releasing pressure on said socket top assembly allows said springs expand and thereby to move said socket top assembly away from said socket base, and causing said ZIF shoulders to move into engagement with said chip in a path guided by said ZIF guide posts and said ZIF link blocks.

16. A removable chip socket for mounting on a circuit board, said circuit board containing electrical leads, and said removable chip socket for holding an electrical chip with electrical conductors in electrical contact with said circuit board, said removable chip socket comprising:
a socket base configured for releasable mounting on said circuit board, for positioning and securing said electrical chip with electrical conductors;
a chip-securing collar attached to said socket base for securing said electrical chip in accurate alignment in said socket base;
an interposer, for contact with said electrical leads of said printed circuit and said conductors of said chip; and
one or more attachment pins for releasably attaching said socket base to said circuit board.

17. The removable chip socket of claim 16, in which said chip securing collar comprises a socket top assembly, one or more springs enclosed in one or more spring wells in said socket base and said socket top assembly, and one or more ZIF guide posts, one or more ZIF link blocks, one or more ZIF shoulders, and a plurality of connecting pins which interfit with said ZIF guide posts, ZIF link blocks, and ZIF shoulders, whereby pressing on said socket top assembly biases said springs in said spring wells, and moves said socket top assembly toward said socket base, and also moves said ZIF shoulders in a path guided by said ZIF guide posts and said ZIF link blocks, to a position away from engagement with a chip in said removable chip socket, and whereby releasing pressure on said socket top assembly allows said springs expand and thereby to move said socket top assembly away from said socket base, and causing said ZIF shoulders to move into engagement with said chip in a path guided by said ZIF guide posts and said ZIF link blocks.
